(19) United States
(12) Patent Application Publication
(10) Pub. No.: US 2025/0226226 A1
(43) Pub. Date: Jul. 10, 2025

(54) STRESS MODULATION OF NITRIDE LAYERS USING CHEMICAL VAPOR DEPOSITION AND HOT ION IMPLANTATION

(71) Applicant: Applied Materials, Inc., Santa Clara, CA (US)

(72) Inventors: Rajesh PRASAD, Lexington, MA (US); Fernando Antonio REBOLLEDO USCANGA, Rockport, MA (US); Shan TANG, Middleton, MA (US); Wayne CHEN, Newton, MA (US); Godwin John NTUK, Lynn, MA (US); Jialiang WANG, Milpitas, CA (US); Guangyan ZHONG, Sunnyvale, CA (US); Aditya SUNDARAM, Santa Clara, CA (US); Shweta HARDIKAR, Milpitas, CA (US); Edwin A. AREVALO, Beverly, MA (US); Kyu-Ha SHIM, Andover, MA (US)

(73) Assignee: Applied Materials, Inc., Santa Clara, CA (US)

(21) Appl. No.: 19/008,022

(22) Filed: Jan. 2, 2025

Related U.S. Application Data
(60) Provisional application No. 63/617,676, filed on Jan. 4, 2024.

(51) Int. Cl. H01L 21/266; H01L 21/02

(52) U.S. Cl. CPC H01L 21/266; H01L 21/0217; H01L 21/02348

(57) ABSTRACT

Techniques for generating and maintaining a low stress nitride layer after a low temperature anneal, including the operations of providing a substrate, the substrate including a nitride layer formed by PECVD; heating the substrate to an elevated temperature; and performing a hot implant by implanting the substrate at the elevated temperature between 150° C. and 700° C.

### RELATED APPLICATIONS

This application claims priority to U.S. provisional patent application Ser. No. 63/617,676, filed Jan. 4, 2024, entitled STRESS MODULATION OF NITRIDE LAYERS USING CHEMICAL VAPOR DEPOSITION AND HOT ION IMPLANTATION, and incorporated by reference in its entirety.

### FIELD

The present embodiments relate to device processing, and more particularly, to improved low dielectric constant layers for electronic devices.

### BACKGROUND

In the present day, insulator layer, such as nitride layers may be deployed in various stages of device processing. In some examples, nitride layers may be used as stress liners in transistor devices while in other examples the nitride layers may be used as hardmasks. Nitride layers may be deposited by various methods including physical vapor deposition (PVD) and chemical vapor deposition (CVD). Depending upon the deposition process, the properties of the nitride layer may vary.

In known applications, silicon nitride (SiN) layers are used for stress liners of CMOS (complementary metal oxide semiconductor) devices. Note that ‘SiN’ as used herein may refer generally to a silicon nitride layer, and not to a particular stochiometry. Thus, as used herein, a “SiN layer” or “silicon nitride layer” may be understood to represent a layer having a mixture predominantly of Si and N, a Si₃N₄ layer, or a layer of similar composition that may include other minor constituents such as hydrogen. In order to improve device performance by increasing carrier mobility, SiN layers for transistor liners may be formed under a condition of tensile stress for N-type MOS devices (NMOS), while the SiN layers are formed under a conduction of compressive stress for P-type MOS (PMOS) devices. In order to achieve such a final device structure having tensile-stress NMOS liners and compressive-stress PMOS liners, a blanket deposition of tensilely stressed SiN layer may be performed over both NMOS and PMOS devices, followed by masking and selective etching of the tensile SiN liner in PMOS devices to remove the tensile SiN liner. A subsequent deposition of a compressively stressed SiN liner may then be performed to coat just the PMOS devices. As such, the known approach to stress engineering for CMOS liners is rather complex and may require different deposition apparatus and different deposition recipes to complete.

With respect to these and other considerations the present disclosure is provided.

### BRIEF SUMMARY

In one embodiment a method to generate and maintain a low stress nitride layer is provided. The method may include providing a substrate, the substrate including a nitride layer formed by PECVD. The method may further include heating the substrate to an elevated temperature, and performing a hot implant by implanting the substrate at the elevated temperature, between 150° C. and 700° C.

In a further embodiment, a method to control properties of a semiconductor device is provided. The method may include providing a substrate comprising a set of P-type transistor devices (P-devices) and a set of N-type transistor devices (N-devices), and performing a blanket deposition process to deposit a nitride layer over the set of P-devices and the set of N-devices. The method may also include performing a masking operation to cover the set of N-devices, and performing a hot implant by implanting the substrate at an elevated temperature.

In another embodiment, a method for selective stress modulation in a semiconductor device is provided. The method may include providing a substrate comprising a set of P-type transistor devices (P-devices) and a set of N-type transistor devices (N-devices). The method may also include performing a blanket deposition process to deposit a nitride layer over the set of P-devices and the set of N-devices, where the nitride layer exhibits a tensile stress at a first stress level after the blanket deposition process. The method may further include forming a mask to selectively cover the set of N-devices; and performing a hot implant by implanting the substrate at an elevated temperature. As such, the nitride layer may exhibit a stable stress level, substantially similar to the first stress level in N-type regions where the nitride layer is disposed over the set of N-devices. where the hot implant generates a second stress level, at least 50% less than the first stress level in P-type regions where the nitride layer is disposed over the set of P-type devices.

### BRIEF DESCRIPTION OF THE DRAWINGS

FIG. 1A-1D show exemplary stages of a substrate during processing for selective stress control, according to embodiments of the disclosure;

FIG. 1E illustrates a further stage of processing of the substrate of FIGS. 1A-1D;

FIGS. 2A-2J are composite illustrations presenting experimental data for stress control of nitride layers, according to various embodiments of the disclosure; and

FIG. 3 presents a process flow, according to some embodiments.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

In accordance with some embodiments, novel processing techniques entail implantation of CVD-deposited layers, and in particular, nitride layers formed by CVD. According to various embodiments of the disclosure, these nitride layers may be employed as liners for transistor devices, where control of the stress state in the nitride liners may aid in enhancing device properties. Example nitride layers include SiN, deposited by a plasma-enhanced CVD (PECVD) technique. As detailed in the disclosure to follow, PECVD nitride layers may be suitably treated to provide more process window for controlling device properties using ion implantation procedures that are subsequently employed to manage the stress in the PECVD layers.

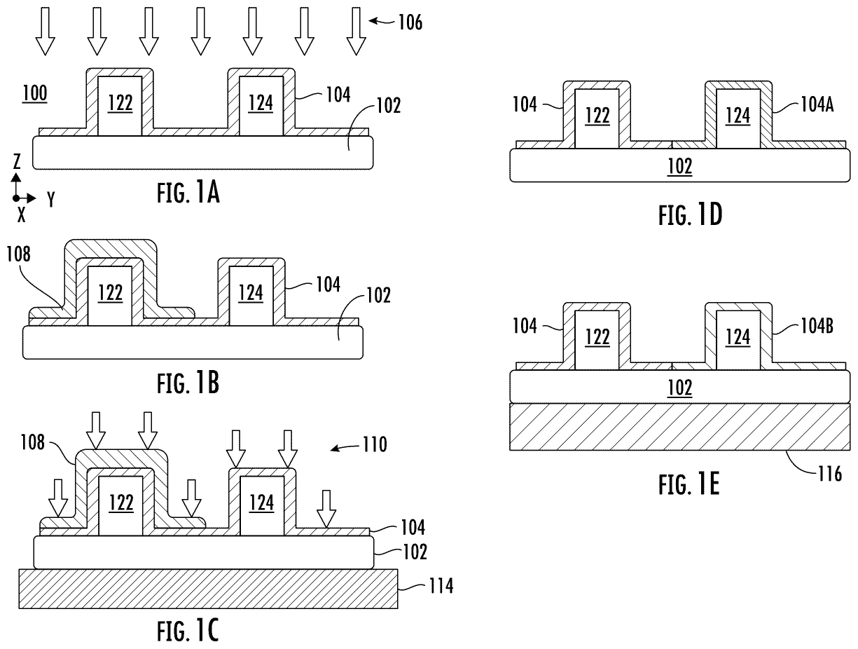

FIG. 1A-1D show exemplary stages of a substrate during processing for selective stress control, according to embodiments of the disclosure. Turning to FIG. 1A there is shown one stage of processing a device 100. The device 100 may represent a semiconductor device that includes a plurality of transistors, including memory devices, logic devices, CMOS devices, and so forth. In one example, illustrated in FIG. 1A, the device 100 may include an NMOS device 122 and a PMOS device 124. At the stage of processing illustrated in FIG. 1A the NMOS device 122 and the PMOS device 124 may each include gate structures, source/drain structures used to form transistors, as known in the art. These devices may be formed on or within an underlying substrate, shown as substrate 102. In the operation depicted in FIG. 1A, a layer 104 is formed on the PMOS device 124 and the NMOS device 122, using depositing species 106.

In one example, the depositing species 106 are provided in a processing apparatus that performs a PECVD process. In some embodiments, the layer 104 is a silicon nitride (SIN) layer. In some embodiments, the layer 104 is used as a stress liner to manage properties of the NMOS device 122 and PMOS device 124. In particular embodiments, the PECVD process used to deposit the layer 104 may employ a capacitively coupled plasma, operating at a suitable frequency, such as 13.6 MHz, as known in the art. In some embodiments suitable precursor gases for depositing a silicon nitride layer to act as layer 104 include silane (SiH₄), nitrogen (N₂), and ammonia (NH₃).

According to embodiments of the disclosure, the flow rates of the precursor gases and the power delivered by the plasma source are used to modify the composition, density and deposition rate of an SiN film used as layer 104. Control of these latter three parameters in turn, may control the stress in the layer 104, as-deposited. Therefore by modulating the gas flows or by adjusting the power delivered by the plasma source, the stress properties of the layer 104 at the stage in FIG. 1A may be controlled.

According to various embodiments of the disclosure, the layer 104 is deposited by a PECVD process at elevated substrate temperature, and in particular in a range between 300° C. and 500° C., between 350° C. and 450° C., and in some embodiments, at a temperature in a range of 390° C. to 410° C. Again, by varying the substrate temperature during deposition of the layer 104, the stress in the layer 104 will vary.

According to particular non-limiting embodiments of the disclosure, the substrate 102 may be place upon a heater that heats the substrate during the deposition of layer 104, where the heater is situated at the bottom of a PECVD chamber with a faceplate at the top of the PECVD chamber being separated from the substrate 102 by approximately 1 cm. By adjusting the spacing between faceplate and substrate 102, the stress state of layer 104 may also be adjusted.

In various embodiments, the layer 104 may be deposited at a suitable thickness and suitable stress state to generate a substantial affect on the properties of the device 100. Examples of suitable thickness for layer 104 range from 20 nm to 100 nm according to some non-limiting embodiments. Examples of suitable levels of stress are between 500 MPa tensile and 2500 MPa tensile in accordance with other non-limiting embodiments. Note that in various embodiments, the substrate 102 may be exposed to ultraviolet radiation (UV) after deposition in order to increase the magnitude of tensile stress in the layer 104, as deposited. For example, a PECVD nitride film may exhibit a stress level of 1000 MPa or less under certain deposition conditions. Suitable UV treatment may increase the level of tensile stress in a PECVD SiN layer by more than a factor of 2.

Turning to FIG. 1B, there is shown a subsequent instance or stage that takes place after the layer 104 has been deposited. At this stage, the layer 104 is arranged over the NMOS device 122 and the PMOS device 124, and may exhibit a targeted tensile stress that exhibits a similar force on both the NMOS device 122 and the PMOS device 124. As further shown in FIG. 1B, at this stage a mask layer 108 is formed on part of the substrate 102. In some embodiments, the mask layer 108 may be a photoresist mask that is formed by blanket deposition of a photoresist layer, followed by lithographic patterning according to known methods. In the instance of FIG. 1B the mask layer 108 is formed over the NMOS device 122, with openings in the mask layer 108 in the region of the PMOS device 124, so the PMOS device 124 is not covered by photoresist material or other mask material.

Turning to FIG. 1C, there is shown a subsequent stage where the substrate 102 is heated to an elevated temperature. In some embodiments the elevated temperature may be between 150° C. and 700° C. The substrate 102 may be heated by any suitable means, such as using a heated platen, heated by convection, heated in an oven, heated using a radiation source, and so forth. In the example of FIG. 1C the substrate 102 is shown as disposed on a platen 114, which platen may be a heated platen. When the substrate 102 has been heated to the elevated temperature, as shown in FIG. 1C, a hot implant is conducted to implant an implant species 110 into materials on the substrate 102. According to various non-limiting embodiments, the implant species 110 may be ions that have an energy in the range 0.2 keV to 120 keV. Suitable implant species according to different embodiments include at least one of: carbon, nitrogen, silicon, germanium, helium, neon, and argon. The energy of the implant species 110 may be chosen so that the implant species 110 are incorporated in targeted layers of the device 100, and not incorporated, or incorporated to a lesser extent in other layers. For example, in the instance of FIG. IC, the energy of the implant species 110 may be adjusted so the implant species are incorporated in the layer 104 in the regions of PMOS device 124, where the layer 104 is uncovered, are not incorporated in the substrate 102, subjacent the layer 104, are incorporated in the mask layer 108, but are not in the layer 104 is the regions of the NMOS where the layer 104 is subjacent the mask layer 108. In some embodiments, the dose of the implant species in the layer 104 is chosen so that an implant concentration of 1E20/cm³ up to3.5E22/cm³ is generated in the layer 104.

According to various embodiments of the disclosure, the hot implant of FIG. 1C may be performed at a at a 0 deg tilt angle with respect to a normal to a main plane of the substrate (in this illustration, the X-Y plane of the Cartesian coordinate system shown). Such a configuration may be sufficient to induce the required stress change in a PMOS transistor, for example, to improve the PMOS hole mobility and associated drive current. However, in accordance with additional embodiments, it may be beneficial to perform the hot implant at a non-zero tilt angle. Generally, the hot implant may be performed at a tilt angle whose value is in the range of 0 deg to 80 deg. One benefit of using an angled implant (non-zero tilt angle with respect to normal) is the ability to impact the vertical sidewall (see, e.g., sidewall 115) and thus to implant into an SiN layer along the sidewall so as to modify the SiN stress along the vertical sidewall of a transistor gate. According to particular embodiments where an angled implant is needed, the substrate may need to be rotated in the x-y plane. For example, in a device structure where the PMOS transistors are all oriented in the same direction, then a 4-step rotation sequence may be sufficient. For example the substrate may be rotated 4 times (0, 90, 180, 270 deg) during an angled implant. The number of rotations may be increased from 4 to as many as is needed for uniformity purposes. For example, to perform 8 rotations, the substrate would be rotated every 45 deg; with 16 rotations, the substrate would be rotated every 22.5 deg.

Turning to FIG. 1D, there is shown a subsequent instance after the completion of the stage of FIG. IC. At this stage, as a result of the hot ion implant at the stage of FIG. 1C, an altered layer 104B has been formed over the PMOS device 124, while the layer 104 remains in place over the NMOS device 122. The layer 104 in the region of the NMOS device 122 may retain the original properties of the layer 104, or a substantial stress, such as a high level of tensile stress. Note that the altered layer 104A may also exhibit a lower level of tensile stress the tensile stress magnitude in layer 104.

FIG. 1E illustrates a further stage of processing of the substrate of FIGS. 1A-1D. In this illustration, there is shown a subsequent instance after the completion of the stage of FIG. 1D. At this stage, the device 100 has been subject to one or more processes that exposed the device to an elevated temperature. The processes may include subjecting the substrate 102 to elevated temperatures of several hundred degrees or more, representative of processes that may take place after the stage of device formation of FIG. 1D. At this stage, a relaxed layer 104B is retained over the region of the PMOS device 124, with a lower level of stress that in the layer 104 that is disposed in the NMOS region. The relaxed layer 104B may retain a lower stress level similar to the stress level of layer 104A, even after being subjected to more thermal budget that is a consequence of further processing. As such, the stress generated in the PMOS device 124 will exhibit less deleterious effect on the PMOS properties, where higher levels of tensile stress tend to retard hole mobility.

### Experiments

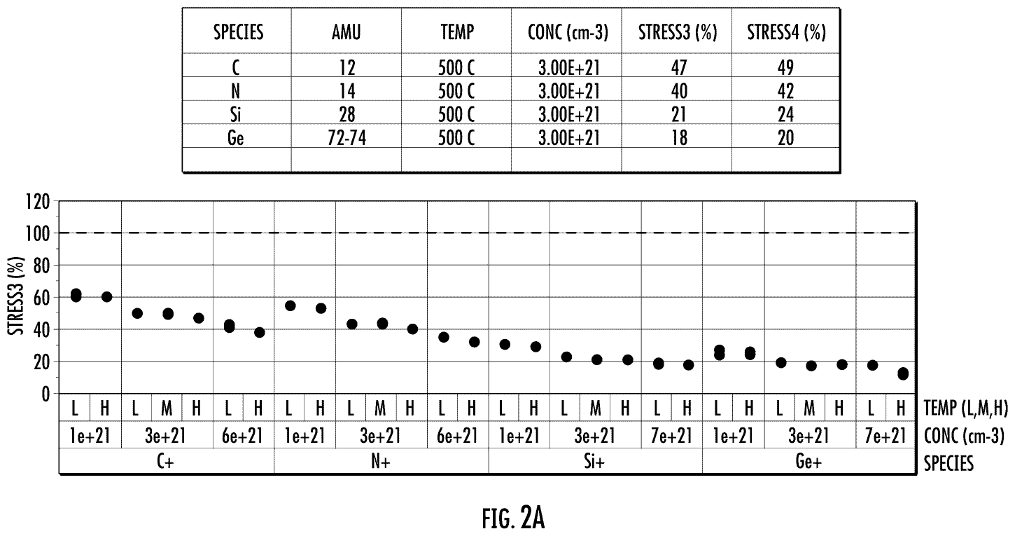

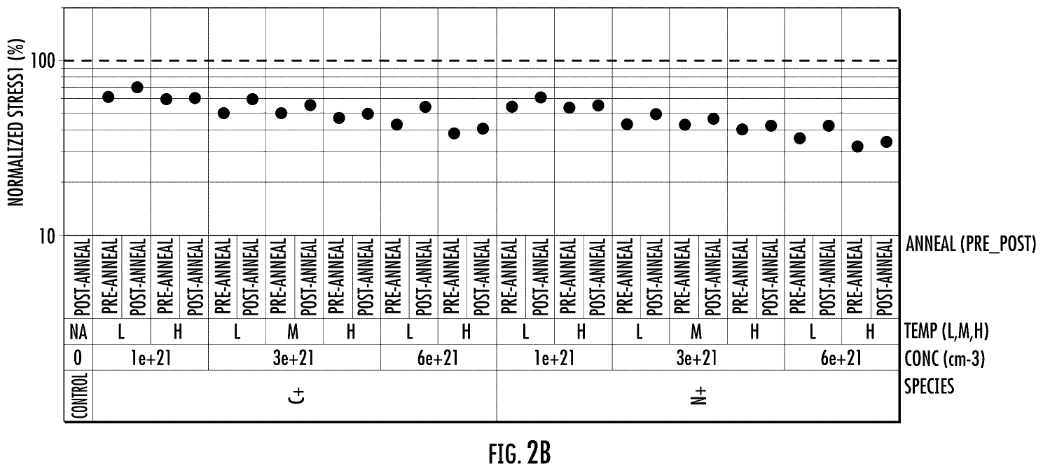

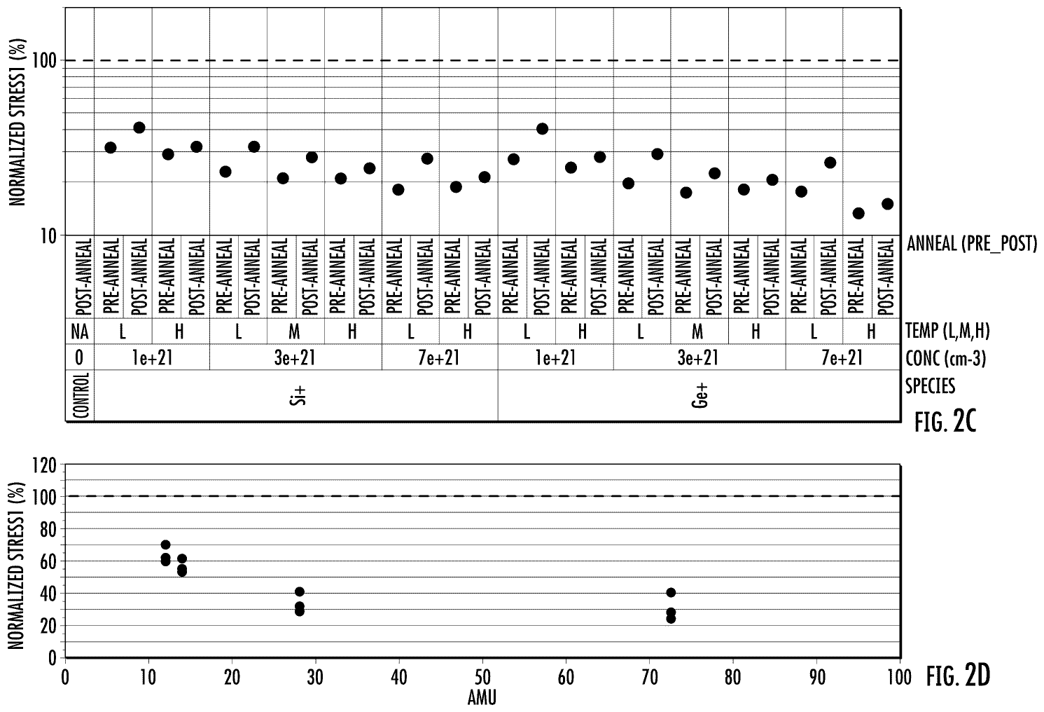

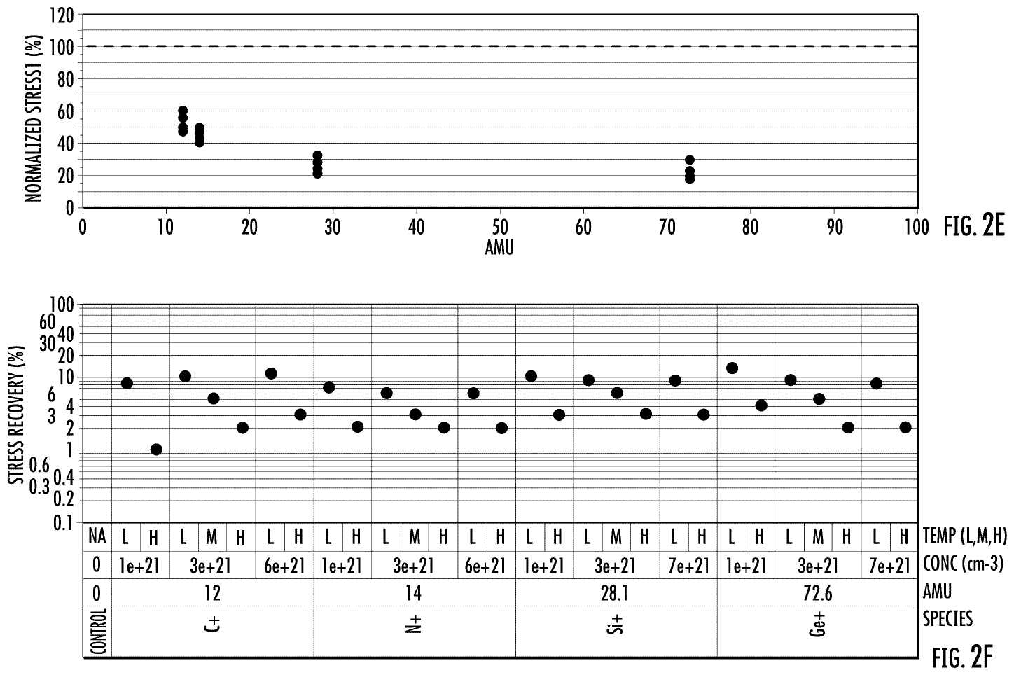

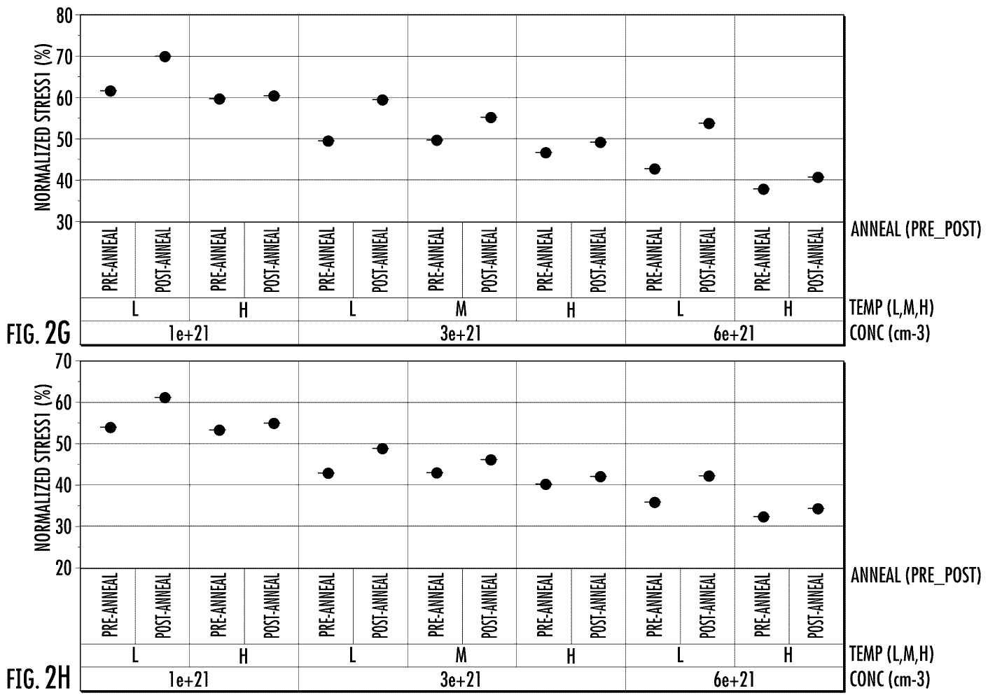

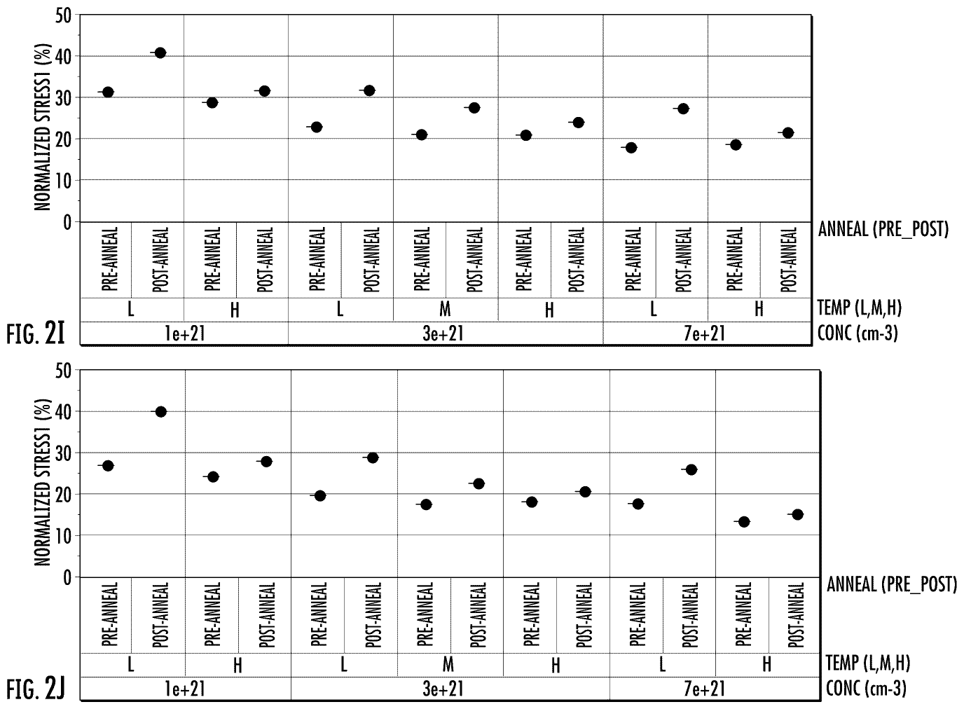

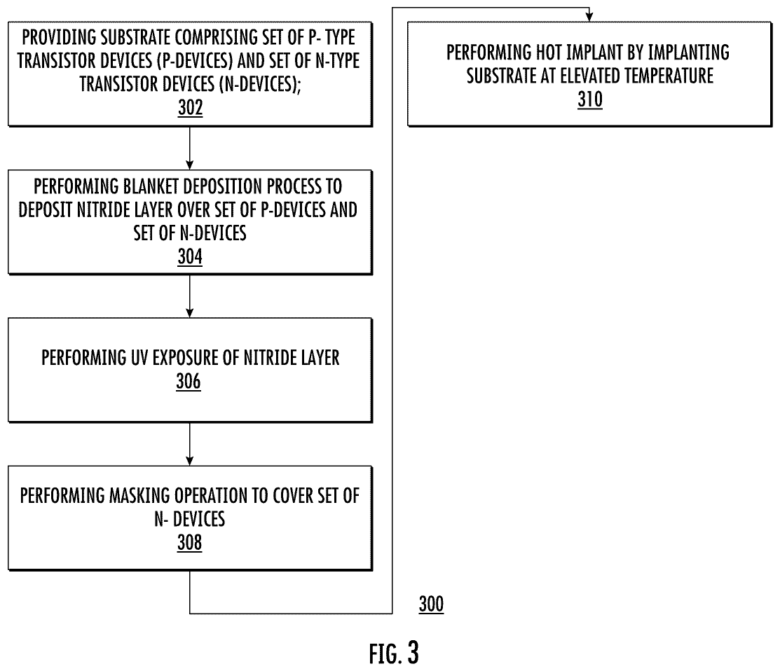

FIGS. 2A-2J are composite illustrations presenting experimental data for stress control of nitride layers, according to various embodiments of the disclosure.

In FIG. 2A there are shown sets of experimental data in graphical form and in tabular form that present the relative decrease in PECVD nitride layer stress caused by the hot implantation according to embodiments of the disclosure. In this example, and others to follow, the silicon nitride layer was deposited by PECVD to have an initial thickness of 32 nm, and was subjected to a targeted UV exposure to increase the magnitude of tensile stress in the silicon nitride layer, before hot implantation. The tabular data presents select data from the graph that shows the relative decrease in stress after hot implantation at 500° C. substrate temperature and post-implant annealing at 500° C. for four different implant species: C, N, Si, and Ge. The ion dose and ion energy were selected for each hot implant so as to generate an implanting species concentration of 3E21/cm³ into the 32 nm SiN layer after implantation. The column entitled “stress3” presents the relative reduction in tensile stress between the as-deposited SiN layer and the tensile stress after hot implant. In particular, the data is presented as a ratio of stress after implant to stress before implant expressed in percentage. As illustrated, in all cases the reduction in tensile stress is substantial, greater than 50%, meaning the stress after implant is less than 50% of the original stress. The decrease in stress after implant is larger in magnitude as the mass of ions increases from C to Gc.

The column entitled “stress4” presents the relative reduction in tensile stress between the as-deposited SiN layer and the tensile stress after hot implant, and after post implant annealing at 500° C. for five minutes. The post-implant annealing was conducted to assess how well the stress relaxation that is engendered by the hot implantation is retained when the implanted SiN layer is subject to additional “thermal budget” that may represent thermal budget experienced by a device after the hot-implant stage. Again, the stress decrease that is retained is substantial with respect to the stress in the as-deposited SiN layers, with the stress values in all cases being close to those values exhibited by the SiN layers directly after hot implant.

The graph of FIG. 2A provides further data, including the effect of increasing implant species concentration (proportional to ion dose) in the SiN layer, as well as increasing substrate temperature during implant from relatively lower (L, meaning 150° C.), medium (M, meaning 300° C.), and relatively higher (H, meaning 500° C.) on the layer stress after hot implant, without further treatment. The dashed line at 100% represents the relative stress value in the PECVD SiN layer as-deposited. In this example, the amount of stress decrease becomes greater as implant species concentration increases, and as implant temperature increases. Thus, the above results suggest that relatively higher implant temperature may be more effective in reducing layer stress. Note, however, especially for Si and Ge, the stress is similar at M and H temperatures and in some cases, similar at all implant temperatures employed. Thus, for certain applications, such as where a relatively low temperature photoresist layer is used to mask the N-devices, hot implantation at the relatively low end of the (150° C. to 750° C.) hot implantation temperature range may be called for.

In FIG. 2B, there is shown a graph that depicts more details of the effect of implant species, implant dose, implant temperature, and post-implant annealing on the stress relaxation in a PECVD silicon nitride layer that is subject to hot implantation and post-implant annealing, according to embodiments of the disclosure. In FIG. 2B, the implanting species are carbon (C⁺) and nitrogen (N⁺). The implant temperature was varied over a temperature range within the range of 100° C. to 700° C. from a relatively lower temperature (L), a medium temperature implant (M), and a relatively higher temperature implant (H). The ion dose was also varied so as to vary concentration of the implanting species as shown, between 1E21/cm³ and 6E21/cm³. After implantation, a post-implant anneal was conducted at 500° C. for 5 min. The Y-axis in this illustration and others to follow depicts the normalized amount of tensile stress of the silicon nitride layer after implantation and post-implant annealing, normalized to the tensile stress exhibited by a control unimplanted silicon nitride layer exposed to the same post-implant anneal, without being subjected to a high temperature implant. As illustrated, the SiN layers implanted and annealed according to the present embodiments all exhibit a lower level of stress as compared to the control sample. The level of stress in the SiN layer also decreases with increasing implant temperature from L to H, with increasing ion dose to generate an implanting species concentration up to 6E21/cm³. Moreover, the stress reduction is greater using nitrogen ions as opposed to carbon ions for all conditions studied.

In FIG. 2C there is shown a set of data analogous to that data of FIG. 2B, for silicon ions (Si⁺) and germanium ions (Ge⁺) used as implanting species. In this case, the dose ranges up to a dose concentration of implanting species up to 7E21/cm^{3.}. The qualitative trends with increasing implant temperature and increasing concentration are the same as in FIG. 2B. Moreover, the stress reduction is greater using silicon ions as opposed to nitrogen ions for all conditions studied, and is still greater using germanium ions as opposed to silicon ions.

Turning to FIG. 2D there is shown a graph plotting the normalized stress in a PECVD SiN layer (with respect to an annealed, unimplanted SiN layer) as a function of atomic mass (amu) for different implanting species, (C, N, Si, and Ge) after post-implant annealing. In this example, the ion dose is arranged to generate a concentration of implanting species of 1E21/cm³. Note that the relative reduction in SiN layer stress is up to 75% for Ge, while the effect of increasing amu on stress reduction is greatest between C, N and Si, with marginal improvement when amu is increased between Si and Ge.

Turning to FIG. 2E there is shown a graph plotting the normalized stress in a PECVD SiN layer (with respect to an annealed, unimplanted SiN layer) as a function of atomic mass (amu) for different implanting species, (C, N, Si, and Ge) after post-implant annealing. In this example, the ion dose is arranged to generate a concentration of implanting species of 3E21/cm³. Note that the effect on stress reduction at this ion dose is similar to the effect shown in FIG. 2C, and the relative reduction in SiN layer stress is up to 75% for Ge. Again, the effect of increasing amu on stress reduction is greatest between C, N and Si, with marginal improvement when amu is increased between Si and Ge.

As noted above, after post-implant annealing, a modest increase in stress takes place, while the overall level of layer stress in a SiN layer implanted according to the present embodiments is much lower than the stress level in an unimplanted SiN layer, as deposited, or after annealing. Turning to FIG. 2F there is shown a graph that depicts the level of stress recovery in a PECVD SiN layer after post-implant anneal. In particular, the Y-axis depicts the percentage increase in stress between a SiN layer subjected to a hot implant, between the stress level immediately after hot implant, and the stress level after the SiN layer is subjected to a post-implant anneal at 500° C. for 5 minutes. Thus, a relatively lower increase in the stress recovery is desirable. As shown in FIG. 2F, the relative recovery of stress decreases as a function of increasing implant temperature, meaning that the higher implant temperature for all implant species, C, N, Si, and Ge. Note that the relative stress recovery is not substantially or systematically affected by increasing ion dose. In other words, the relative stress recovery varies by less than 10% with changes in ion dose. However, as shown in FIG. 2A and FIG. 2B, the relative reduction is stress with respect to unimplanted layers does improve with increased ion dose, meaning that overall, increased ion dose leads to a lower residual stress after post implant annealing, since the relative recovery (increase) in stress is no worse at high dose than at low dose. Said differently, performing a hot implant at a relatively higher implant temperature and relatively higher ion dose serves to ‘lock in’ a relatively larger decrease in tensile stress, that is preserved even after the layers are subjected to further thermal budget, as evidenced by the data for stress after post-implant annealing is completed.

Nonetheless, the present embodiments provide a flexible approach to tailor post-processing properties of a layer, such as a SiN nitride layer, according to considerations of appropriate implant species, preferred ion dose, and so forth. Turning to FIG. 2G, there is shown a graph depicting the effect of ion concentration and implant temperature on SiN layer stress reduction, just for carbon species. Again, the stress reduction increases with increasing implant temperature and with increasing ion concentration, up to 6E21/cm³ implant species concentration, with some recovery of stress after implant. However, at the ion concentration corresponding to 6E21/cm³ implant species concentration and high implant temperature, just a small increase in stress is seen after post implant anneal as opposed to the stress after hot implantation. For example, the normalized stress after anneal at this level of ion concentration is just ˜40%.

Turning to FIG. 2H, there is shown a graph depicting the effect of ion concentration and implant temperature on SiN layer stress reduction, just for nitrogen species. Again, the stress reduction increases with increasing implant temperature and with increasing ion concentration, up to 6E21/cm³ implant species concentration, with some recovery of stress after implant. However, at the ion dose corresponding to 6E21/cm³ implant species concentration and high implant temperature, just a small increase in stress is seen after post implant anneal as opposed to the stress after hot implantation. For example, the normalized stress after anneal at this level of ion concentration is just ˜35%.

Turning to FIG. 21, there is shown a graph depicting the effect of ion concentration and implant temperature on SiN layer stress reduction, just for silicon species. Again, the stress reduction increases with increasing ion concentration, up to 7E21/cm³ implant species concentration, with some recovery of stress after implant. However, the stress reduction is generally more pronounced when implant temperature increases from L to M, with little or no further stress reduction when implant temperature increases from M to H.

Turning to FIG. 2J, there is shown a graph depicting the effect of ion concentration and implant temperature on SiN layer stress reduction, just for germanium species. Again, comparing the trend in final stress after post-implant annealing, the stress reduction increases with increasing ion concentration, up to 7E21/cm³ implant species concentration, with some recovery of stress after implant. The stress reduction also increases with increasing implant temperature, while the stress reduction is generally more pronounced when implant temperature increases from L to M, with little or no further stress reduction when implant temperature increases from M to H.

It is noted that in further experiments conducted by the present inventors, when post-implant annealing was conducted at temperatures up to 1000° C., at least under some conditions of implant species, concentration, and implant temperature, the SiN layer stress tended to increase toward the stress values exhibited in SiN layers as-deposited, before hot implantation. Thus, management of post-implant thermal budget for device after hot implant may be in order to ensure that the reduced tensile stress exhibited in targeted regions, such as PMOS, is retained.

FIG. 3 presents a process flow 300. At block 302, a substrate is provided that includes a set of P-type transistor devices (P-devices) and a set of N-type transistor devices (N-devices).

At block 304, a blanket deposition process if performed to deposit a nitride layer over the set of P-devices and the set of N-type transistor devices. In some examples, the nitride layer may be a silicon nitride layer that is deposited by PECVD.

At block 306, the nitride layer may be subject to ultraviolet (UV) exposure. The UV exposure may be performed to increase the level of stress in the nitride layer as an example.

At block 308, a masking operation is provided to cover the set of N-devices. In one example, the masking operation may be provided by depositing a blanket resist layer over the entire substrate, followed by lithographic patterning the resist layer so that the resist layer remains over the set of N-devices, while the resist layer is absent over the P-devices.

At block 310, a hot implant is performed at elevated temperature to implant species into the substrate, and in particular into the nitride layer in regions of the P-devices. In other words, the implant species, implant energy, and implant dose may be chosen to implant a suitable concentration of implant species into the nitride layer over the P-devices, while not implanting the implant species into the nitride layer of the N-devices, by virtue of the presence of the resist layer. In some examples, where the nitride layer is SiN, the implant species may be one of C, N, Si, or Ge. In some examples, the ion dose of implant species may be such to generate an implant species concentration in the nitride layer of at least 1E21/cm³. In some examples, the hot implant may be performed at a zero degree tilt with respect to a normal to a main plane of the substrate, while in other examples, the hot implant may be performed at a non-zero degree tilt. As such, a large reduction in stress, in particular, tensile stress, may be generated in the nitride layer, in particular in regions of the P-devices. This large reduction in stress may substantially persist, even after the substrate is subjected to post-implantation thermal budget, such as extended annealing at temperatures in the range of 500° C.

In sum, various provide the advantage of achieving better stress reduction in a layer subjected to hot implantation by using relatively heavier atomic mass unit species and by increasing ion concentration, from 1E21cm-3 to 7E21cm-3, as well as by increasing implant temperature in the range 150° C. to 550° C. Another advantage provided by the present embodiments is the ability to reduce the stress recovery after post-implant thermal treatment by increasing the implant temperature in the range 150° C. to 550° C., where stress recovery is defined as the stress change from post-implant layer stress to the layer stress after a subsequent post-implant thermal treatment of the order 500° C. for 5 minutes.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method to generate and maintain a low stress nitride layer, comprising:
providing a substrate, the substrate including a nitride layer formed by PECVD;
heating the substrate to an elevated temperature; and
performing a hot implant by implanting the substrate at the elevated temperature, wherein the elevated temperature of the hot implant is between 150° C. and 700° C.

2. The method of claim 1, wherein the nitride layer comprises an SiN layer.

3. The method of claim 1, wherein the elevated temperature of the hot implant is no more than 500° C.

4. The method of claim 1, wherein the nitride layer exhibits a first stress level of at least 1500 MPa before the hot implant, and wherein the nitride layer exhibits a second stress level after the hot implant, the second stress level being less than 50% of the first stress level.

5. The method of claim 4, wherein, when the substrate is annealed at 500° C. after the hot implant for five minutes, the nitride layer exhibits a third stress level that is no more than 10% greater than the second stress level, and is less than 50% of the first stress level.

6. The method of claim 1, wherein the hot implant is carried out an energy of 0.2 keV to 120 keV, wherein the hot implant comprises an implant species comprising at least one of: carbon, nitrogen, silicon, germanium, helium, neon, and argon.

7. The method of claim 6, wherein the hot implant generates an implant species concentration of 1E20/cm³ or greater.

8. The method of claim 1, wherein the nitride layer is deposited at an elevated substrate temperature, between 300° C. and 500° C.

9. The method of claim 1, further comprising subjecting the nitride layer to an ultraviolet exposure after the nitride layer is deposited and before the performing the hot implant.

10. A method to control properties of a semiconductor device, comprising:
providing a substrate comprising a set of P-type transistor devices (P-devices) and a set of N-type transistor devices (N-devices);
performing a blanket deposition process to deposit a nitride layer over the set of P-devices and the set of N-devices;
performing a masking operation to cover the set of N-devices; and
performing a hot implant by implanting the substrate at an elevated temperature.

11. The method of claim 10, wherein the nitride layer is deposited at an elevated substrate temperature, between 300° C. and 500° C.

12. The method of claim 10, further comprising subjecting the nitride layer to an ultraviolet exposure after the nitride layer is deposited and before the performing the hot implant.

13. The method of claim 10, wherein the nitride layer comprises an SiN layer.

14. The method of claim 10, wherein the elevated temperature is between 150° C. and 700° C.

15. The method of claim 10, wherein the hot implant is carried out an energy of 0.2 keV to 120 keV, wherein the hot implant comprises an implant species comprising at least one of: carbon, nitrogen, silicon, germanium, helium, neon, and argon.

16. The method of claim 10, wherein the hot implant generates an implant species concentration of 1E20/cm³ or greater.

17. The method of claim 10, wherein the nitride layer exhibits a first stress level of at least 1500 MPa before the hot implant, and wherein the nitride layer exhibits a second stress level after the hot implant, the second stress level being less than 50% of the first stress level.

18. The method of claim 17, wherein, when the substrate is annealed at 500° C. after the hot implant, the nitride layer exhibits a third stress level that is no more than 10% greater than the second stress level, and is less than 50% of the first stress level.

19. The method of claim 17, wherein, after the hot implant, in the N-type transistor devices, the nitride layer exhibits a fourth stress level that is substantially the same as the first stress level.

20. A method for selective stress modulation in a semiconductor device, comprising:
providing a substrate comprising a set of P-type transistor devices (P-devices) and a set of N-type transistor devices (N-devices);
performing a blanket deposition process to deposit a nitride layer over the set of P-devices and the set of N-devices, the nitride layer exhibiting a tensile stress at a first stress level after the blanket deposition process;
forming a mask to selectively cover the set of N-devices; and
performing a hot implant by implanting the substrate at an elevated temperature,
wherein the nitride layer exhibits a stable stress level, substantially similar to the first stress level in N-type regions where the nitride layer is disposed over the set of N-devices, and wherein the hot implant generates a second stress level, at least 50% less than the first stress level in P-type regions where the nitride layer is disposed over the set of P-type devices.
